(19) United States
(12) Patent Application Publication
(10) Pub. No.: US 2010/0327295 A1
(43) Pub. Date: Dec. 30, 2010

(54) LED PACKAGE STRUCTURE WITH EXTERNAL CUTTING CHAMFER AND METHOD FOR MANUFACTURING THE SAME

(75) Inventors: HSIN-YUAN PENG, Xinwu Township (TW); Chao-Chin Wu, Taipei City (TW); Chia-Tin Chung, Toufen Township (TW)

Correspondence Address: KILE PARK GOEKJIAN REED & MCMANUS, 1200 NEW HAMPSHIRE AVE, NW, SUITE 570, WASHINGTON, DC, 20036, US

(73) Assignee: Paragon Semiconductor Lighting Technology Co., Ltd

(21) Appl. No.: 12/551,682

(22) Filed: Sep. 1, 2009

(30) Foreign Application Priority Data
Jun. 24, 2009 (TW) 98121162

(51) Int. Cl. H01L 33/00

(52) U.S. Cl. 257/88; 438/27; 257/98; 438/28; 257/E33.059; 257/E33.061; 257/E33.067

(57) ABSTRACT

An LED package structure includes a substrate unit, a light-emitting unit, a light-reflecting unit and a package unit. The substrate unit has a substrate body and a chip-placing area, and the substrate body has a cutting chamfer formed on one side thereof. The light-emitting unit has a plurality of LED chips electrically disposed on the chip-placing area. The light-reflecting unit has an annular reflecting resin body surroundingly formed on the substrate body by coating. A distance between an outermost side of the annular reflecting resin body and an outermost side of the substrate body is between 0 and 1.5 mm, and the annular reflecting resin body surrounds the LED chips to form a resin position limiting space. The package unit has a translucent package resin body for covering the LED chips, and the position of the translucent package resin body is limited in the resin position limiting space.

### CROSS-REFERENCE TO RELATED APPLICATION

This application claims priority under 35 U.S.C. §119 to Taiwan Patent Application No. 098121162, filed on Jun. 24, 2009, in the Taiwan Intellectual Property Office, the entire contents of which are hereby incorporated by reference.

### BACKGROUND OF THE INVENTION

1. Field of the Invention

The present invention relates to an LED package structure and a method for manufacturing the same, in particular, to an LED package structure with external cutting chamfer and a method for manufacturing the same.

2. Description of Related Art

The invention of the lamp greatly changed the style of building construction and the living style of human beings, allowing people to work during the night. Without the invention of the lamp, we may stay in the living conditions of ancient civilizations.

Various lamps such as incandescent bulbs, fluorescent bulbs, power-saving bulbs and etc. have been intensively used for indoor illumination. These lamps commonly have the disadvantages of quick attenuation, high power consumption high heat generation, short working life, high fragility, and being not recyclable. Further, the rapid flow of electrons (about 120 per second) through the electrodes of a regular fluorescent bulb causes an unstable current at the onset of lighting a fluorescent bulb, resulting in a flash of light that is harmful to the sight of the eyes. In order to eliminate this problem, a high frequency electronic ballast may be used. When a fluorescent or power-saving bulb is used with high frequency electronic ballast, it saves about 20% of the consumption of power and eliminates the problem of flashing. However, the high frequency electronic ballast is not detachable when installed in a fluorescent or power-saving bulb, the whole lamp assembly becomes useless if the bulb is damaged. Furthermore, because a fluorescent bulb contains a mercury coating, it may cause pollution to the environment when thrown away after damage.

Hence, LED lamp or LED tube is created in order to solve the above-mentioned questions of the prior lamp. The prior art needs to add a metal frame on a PCB in order to conveniently electrically connect LED chips on the PCB by wire bonding. In other words, when the metal frame is pressed by two pressing elements, each LED chip can be electrically disposed on the PCB by a wire bonding process. Hence, the cost and the weight of LED package structure are increased due to the usage of the metal frame, and the PCB needs to create extra width for the metal frame on the PCB.

### SUMMARY OF THE INVENTION

In view of the aforementioned issues, the present invention provides an LED package structure with external cutting chamfer and a method for manufacturing the same. When every two pressing areas beside two opposite sides of each LED chip are respectively pressed by two pressing elements, each LED chip can be electrically disposed on the substrate body by a wire bonding process without increasing the width of the substrate body. Hence, the width of the empty area of the top surface of each substrate body of each LED package structure is very narrow.

To achieve the above-mentioned objectives, the present invention provides an LED package structure with external cutting chamfer, including: a substrate unit, a light-emitting unit, a light-reflecting unit and a package unit. The substrate unit has a substrate body and a chip-placing area disposed on a top surface of the substrate body, and the substrate body has a cutting chamfer formed on one side thereof. The light-emitting unit has a plurality of LED chips electrically disposed on the chip-placing area. The light-reflecting unit has an annular reflecting resin body surroundingly formed on the top surface of the substrate body by coating. A distance between an outermost side of the annular reflecting resin body and an outermost side of the substrate body is between 0 and 1.5 mm, and the annular reflecting resin body surrounds the LED chips that are disposed on the chip-placing area to form a resin position limiting space above the chip-placing area. The package unit has a translucent package resin body disposed on the top surface of the substrate body in order to cover the LED chips, and the position of the translucent package resin body is limited in the resin position limiting space.

To achieve the above-mentioned objectives, the present invention provides an LED package structure with external cutting chamfer, including: a substrate unit, a light-emitting unit, a light-reflecting unit and a package unit. The substrate unit has a substrate body and a chip-placing area disposed on a top surface of the substrate body, and the substrate body has two cutting chamfers respectively formed on two opposite sides thereof. The light-emitting unit has a plurality of LED chips electrically disposed on the chip-placing area. The light-reflecting unit has an annular reflecting resin body surroundingly formed on the top surface of the substrate body by coating. A distance between an outermost side of the annular reflecting resin body and an outermost side of the substrate body is between 0 and 1.5 mm, and the annular reflecting resin body surrounds the LED chips that are disposed on the chip-placing area to form a resin position limiting space above the chip-placing area. The package unit has a translucent package resin body disposed on the top surface of the substrate body in order to cover the LED chips, and the position of the translucent package resin body is limited in the resin position limiting space.

To achieve the above-mentioned objectives, the present invention provides a method of manufacturing an LED package structure with external cutting chamfer, including: providing a substrate module composed of a plurality of substrate units; wherein the substrate module has a plurality of concave grooves and pressing areas formed on a top surface thereof, each concave groove is formed between every two substrate units, and each substrate unit has a substrate body and a chip-placing area disposed on a top surface of the substrate body; pressing every two pressing areas beside each substrate unit in order to electrically disposed a plurality of LED chips on the chip-placing area of each substrate unit; and then selectively executing step (a) or (b).

Moreover, the step (a) is: surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; forming a translucent package resin body on the top surface of the substrate body of each substrate unit in order to cover the LED chips, wherein the position of each translucent package resin body is limited in each resin position limiting space; and cutting the substrate module along the concave grooves into the substrate units.

Furthermore, the step (b) is: cutting the substrate module along the concave grooves into the substrate units; surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; and forming a translucent package resin body on the top surface of the substrate body of each substrate unit in order to cover the LED chips, wherein the position of each translucent package resin body is limited in each resin position limiting space.

Therefore, when every two pressing areas beside two opposite sides of each LED chip are respectively pressed by two pressing elements, each LED chip can be electrically disposed on the substrate body by a wire bonding process without increasing the width of the substrate body. In other words, the width of the empty area of the top surface of each substrate body of each LED package structure is very narrow. That is the same as the above-mentioned definition of the distance between 0 and 1.5 mm. Therefore, the width of the empty area is between 0 and 1.5 mm.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a flowchart of the method of manufacturing an LED package structure with external cutting chamfer according to the first embodiment of the present invention;

FIGS. 1A to 1E are schematic views of the LED package structure with external cutting chamfer according to the first embodiment of the present invention, at different stages of the packaging processes, respectively;

FIG. 2 is a flowchart of the method of manufacturing an LED package structure with external cutting chamfer according to the second embodiment of the present invention; and

FIGS. 2A to 2E are schematic views of the LED package structure with external cutting chamfer according to the second embodiment of the present invention, at different stages of the packaging processes, respectively.

### DETAILED DESCRIPTION OF THE PREFERRED EMBODIMENTS

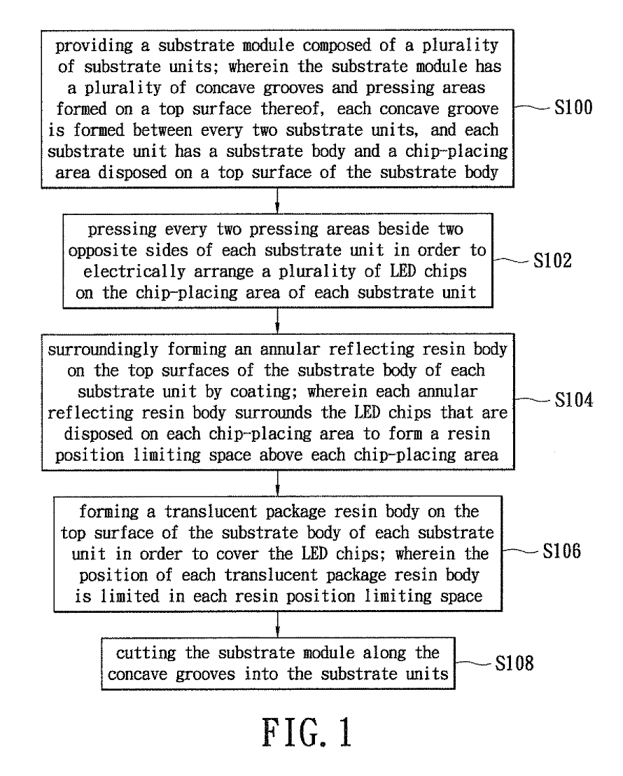

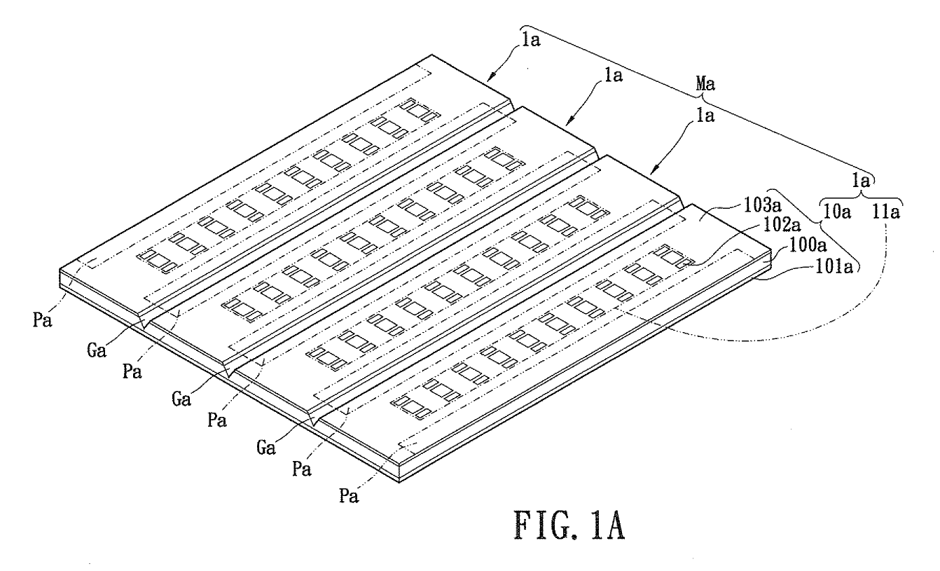

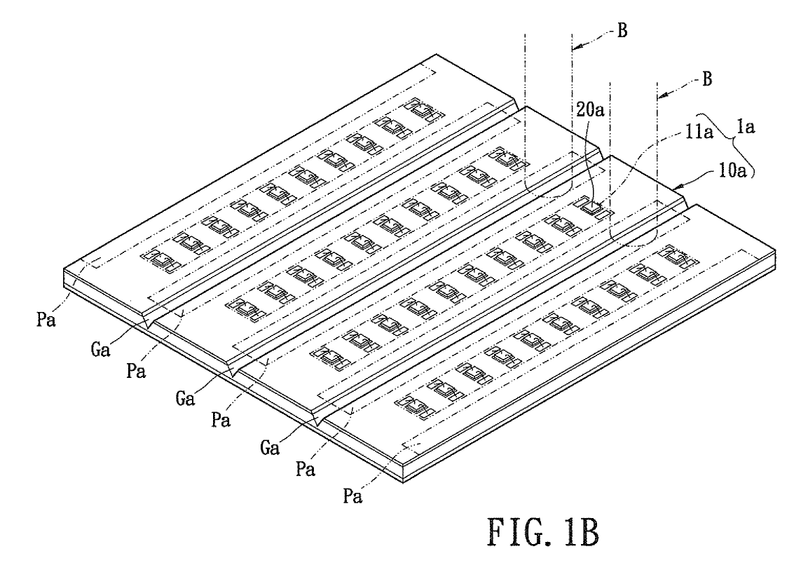

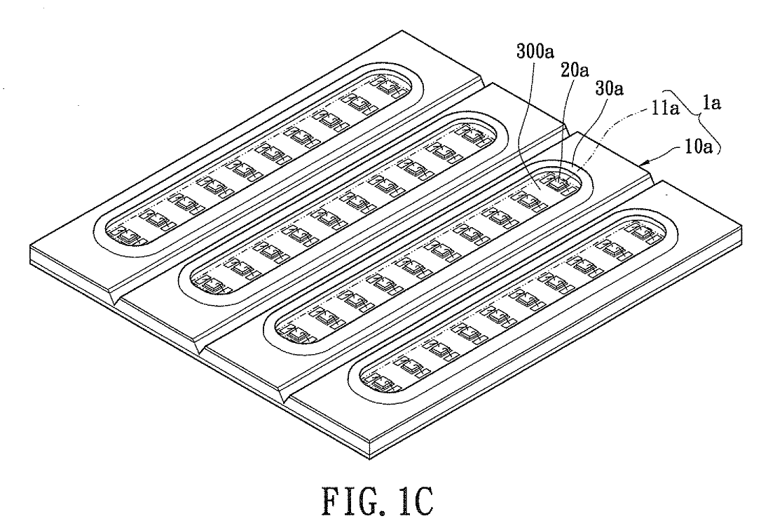

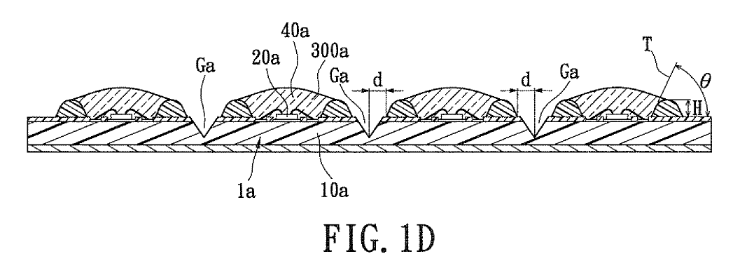

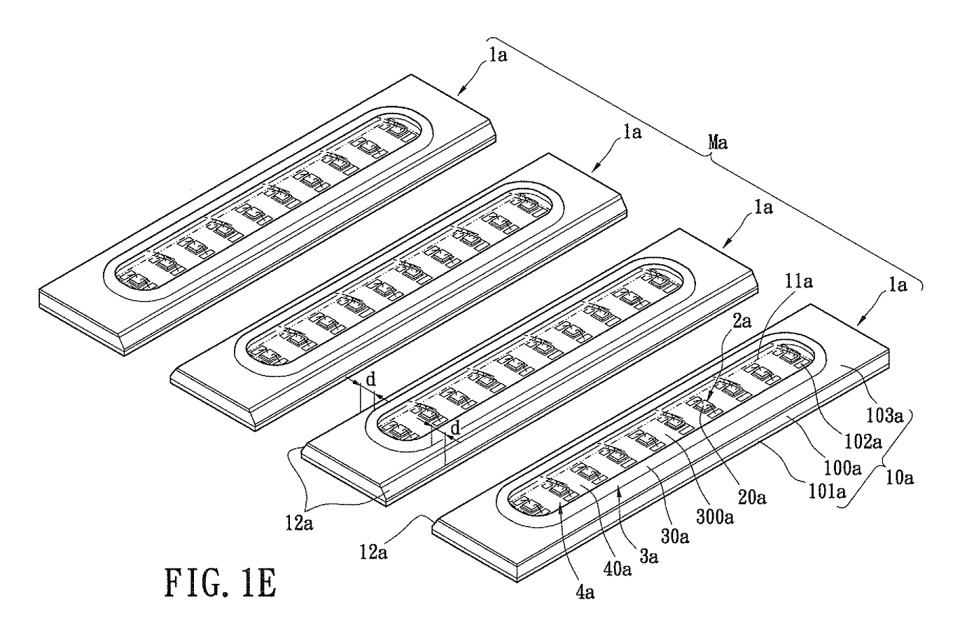

Referring to FIG. 1, the first embodiment of the present invention provides a method of manufacturing an LED package structure with external cutting chamfer. The method includes: providing a substrate module composed of a plurality of substrate units (the substrate module has a plurality of concave grooves and pressing areas formed on a top surface thereof, each concave groove is formed between every two substrate units, and each substrate unit has a substrate body and a chip-placing area disposed on a top surface of the substrate body); pressing every two pressing areas beside two opposite sides of each substrate unit in order to electrically arrange a plurality of LED chips on the chip-placing area of each substrate unit; surroundingly forming an annular reflecting resin body on the top surfaces of the substrate body of each substrate unit by coating (each annular reflecting resin body surrounds the LED chips that are disposed on each chip-placing area to form a resin position limiting space above each chip-placing area); forming a translucent package resin body on the top surface of the substrate body of each substrate unit in order to cover the LED chips (the position of each translucent package resin body is limited in each resin position limiting space); and cutting the substrate module along the concave grooves into the substrate units.

Referring to FIGS. 1 and 1A-1E, the detail descriptions of the first embodiment of the present invention are shown as follows:

Referring to FIGS. 1 and 1A, the method includes providing a substrate module Ma composed of a plurality of substrate units 1a; wherein the substrate module Ma has a plurality of concave grooves Ga and pressing areas Pa formed on a top surface thereof (two of the pressing areas Pa are respectively formed on two opposite outermost sides of the substrate module Ma and the other pressing areas Pa are respectively formed over the concave grooves Ga), each concave groove Ga is formed between every two substrate units 1a, and each substrate unit 1a has a substrate body 10a and a chip-placing area 11a disposed on a top surface of the substrate body 10a (step S100). In addition, each concave groove Ga can be a V-shaped groove or a U-shaped groove. In the first embodiment, each concave groove Ga is a V-shaped groove.

Moreover, each substrate body 10a has a circuit substrate 100a, a heat-dissipating layer 101a disposed on a bottom surface of the circuit substrate 10a, a plurality of conductive pads 102a disposed on a top surface of the circuit substrate 100a, and an insulative layer 103a disposed on the top surface of the circuit substrate 100a in order to expose the conductive pads 102a. Hence, the heat-dissipating efficiency of the circuit substrate 100a is increased by using the heat-dissipating layer 101a, and the insulative layer 103a is a solder mask for exposing the conductive pads 102a only in order to achieve local soldering. However, the above-mentioned definition of the substrate body 10a does not limit the present invention. Any types of substrate can be applied to the present invention. For example, the substrate body 10a can be a PCB (Printed Circuit Board), a flexible substrate, an aluminum substrate, a ceramic substrate, or a copper substrate.

Referring to FIGS. 1 and 1B, the method includes pressing every two pressing areas Pa beside two opposite sides of each substrate unit 1a in order to electrically arrange a plurality of LED chips 20a on the chip-placing area 11a of each substrate unit 1a (step S102). In other words, designer can plan a predetermined chip-placing area 11a on the substrate unit 1a in advance, so that the LED chips 20a can be placed on the chip-placing area 11a of the substrate unit 1a. In the first embodiment, the LED chips 20a are electrically disposed on the chip-placing area 11a of the substrate unit 1a by wire bonding. In addition, when every two pressing areas Pa beside two opposite sides of each LED chip 20a are respectively pressed by two pressing elements B, the LED chips 20a can be electrically connected with the substrate bodies 10a by wire bonding in sequence.

Referring to FIGS. 1 and 1C, the method includes surroundingly forming an annular reflecting resin body 30a on the top surfaces of the substrate body 10a of each substrate unit 1a by coating; wherein each annular reflecting resin body 30a surrounds the LED chips 20a that are disposed on each chip-placing area 11a to form a resin position limiting space 300a above each chip-placing area 11a (step S104). In addition, the step of surroundingly forming each annular reflecting resin body 30a further includes: surroundingly coating liquid resin (not shown) on the top surface of the substrate body 10a of each substrate unit 1a, and then hardening the liquid resin to form the annular reflecting resin bodies 30a. Furthermore, the liquid resin can be coated on the substrate body 10a by any shapes according to different requirements (such as a circular shape, a square or a rectangular shape etc.). In addition, the annular reflecting resin body 30a can be a white thermohardening reflecting body (opaque resin) mixed with inorganic additive, and the cross section of the resin position limiting space 300a has a rectangular shape.

The thixotropic index of the liquid resin is between 4 and 6, the pressure of coating the liquid resin on the top surface of the substrate body 10a is between 350 kpa and 450 kpa, and the velocity of coating the liquid resin on the top surface of the substrate body 10a is between 5 mm/s and 15 mm/s. The liquid resin is surroundingly coated on the top surface of the substrate body 10a from a start point to a termination point, and the position of the start point and the position of the termination point are the same. In addition, the liquid resin is hardened by baking, the baking temperature is between 120° C. and 140° C., and the baking time is between 20 minute and 40 minute.

Referring to FIGS. 1 and 1D, the method includes forming a translucent package resin body 40a on the top surface of the substrate body 10a. of each substrate unit 1a in order to cover the LED chips 20a; wherein the position of each translucent package resin body 40a is limited in each resin position limiting space 300a (step S106). In addition, the top surface of each translucent package resin body 40a can be convex, concave or plane. In the first embodiment, the top surface of each translucent package resin body 40a is convex.

Furthermore, referring to FIG. 1D, each annular reflecting resin body 30a has an arc shape formed on a top surface thereof. Each annular reflecting resin body 30a has a radius tangent T, and the angle θ of the radius tangent T relative to the top surface of the substrate body 10a of each substrate unit 1a is between 40° C. and 50° C. The maximum height H of each annular reflecting resin body 30a relative to the top surface of the substrate body 10a of each substrate unit 1a is between 0.3 mm and 0.7 mm, and the width of a bottom side of each annular reflecting resin body 30a is between 1.5 mm and 3 mm. The thixotropic index of each annular reflecting resin body 30a is between 4 and 6.

In the first embodiment, each LED chip 20a can be a blue LED chip, and each translucent package resin body 40a can be a phosphor body. Hence, blue light beams (not shown) generated by the LED chips 20a (the blue LED chips) can pass through the translucent package resin body 40a (the phosphor body) to generate white light beams (not shown) that are similar to the light source generate by sun lamp.

Referring to FIGS. 1, 1D and 1E, the method includes cutting the substrate module Ma along the concave grooves Ga into the substrate units 1a (S108) in order to finish the manufacture of each LED package structure with external cutting chamfer. In addition, two of the substrate units 1a are two outermost substrate units, and the other substrate units 1a are disposed between the two outermost substrate units. The substrate body 10a of each outermost substrate unit 1a has a cutting chamfer 12a formed on one side thereof, and the substrate body 10a of each of the other substrate units 1a has two cutting chamfers 12a respectively formed on two opposite sides thereof. Moreover, a distance d between an outermost side of each annular reflecting resin body 30a and an outermost side of each substrate body 10a is between 0 and 1.5 mm. If the distance d between the outermost side of each annular reflecting resin body 30a and the outermost side of each substrate body 10a is 0 mm, the surface of the outermost side of each annular reflecting resin body 30a and the surface of the outermost side of each substrate body 10a are on the same plane.

Hence, when every two pressing areas Pa (as shown in FIG. 1B) beside two opposite sides of each LED chip 20a are respectively pressed by two pressing elements B, each LED chip 20a can be electrically disposed on the substrate body 10a by a wire bonding process without increasing the width of the substrate body 10a. In other words, the width of the empty area of the top surface of each substrate body 10a of each LED package structure is very narrow. That is the same as the above-mentioned definition of the distance d between 0 and 1.5 mm. Therefore, the width of the empty area is between 0 and 1.5 mm.

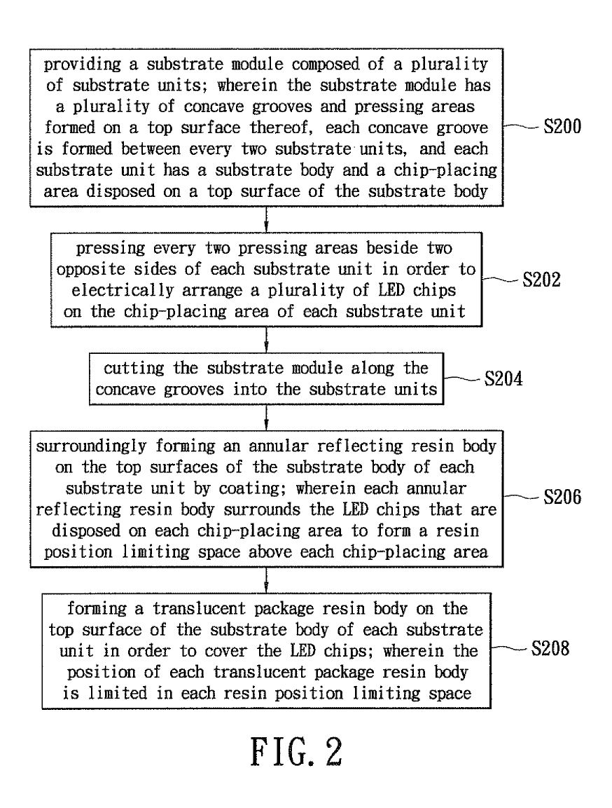

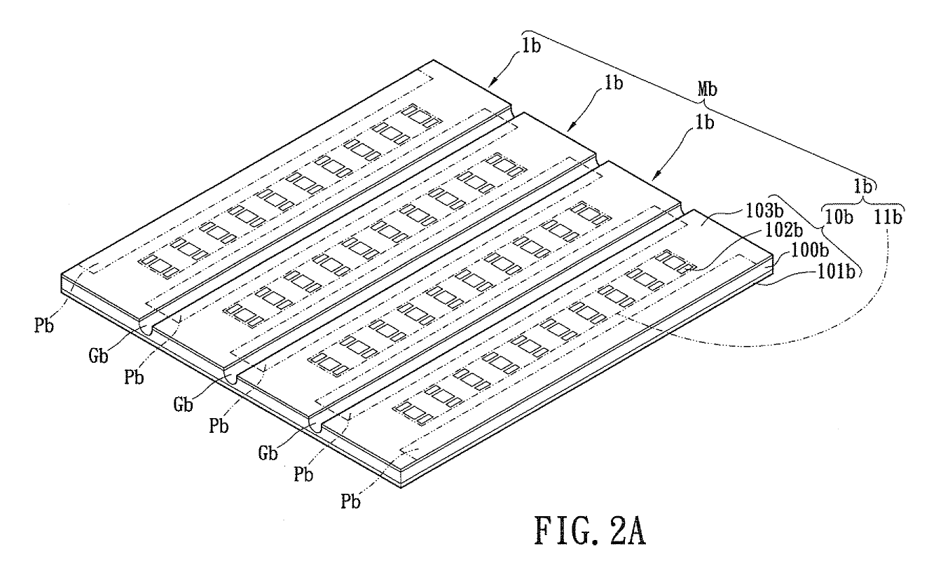

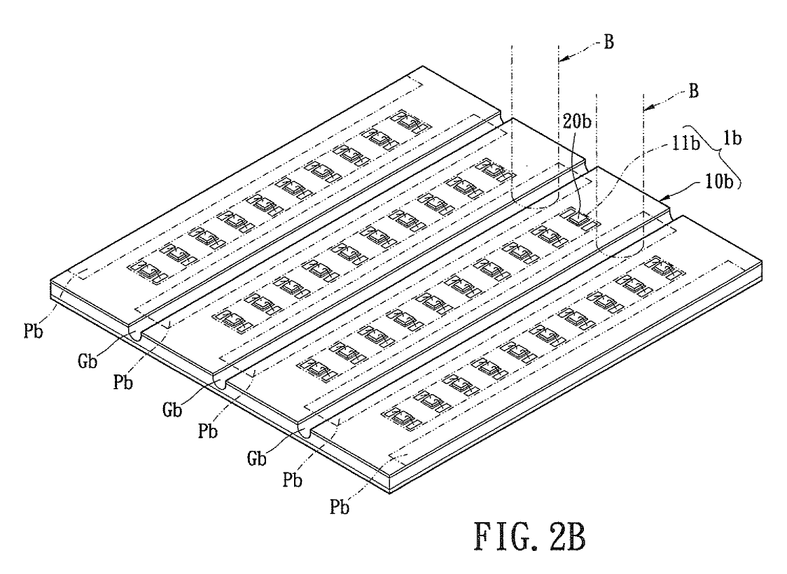

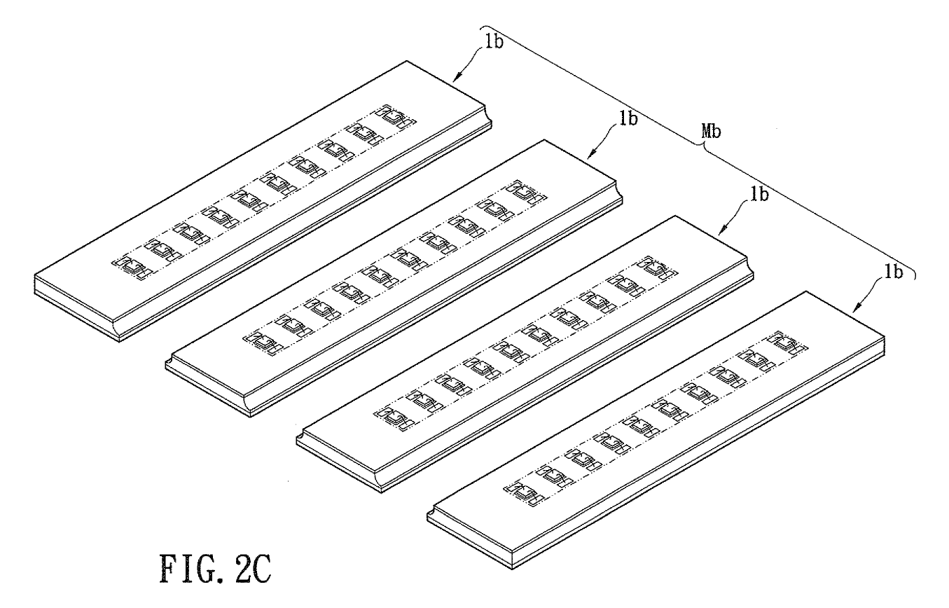

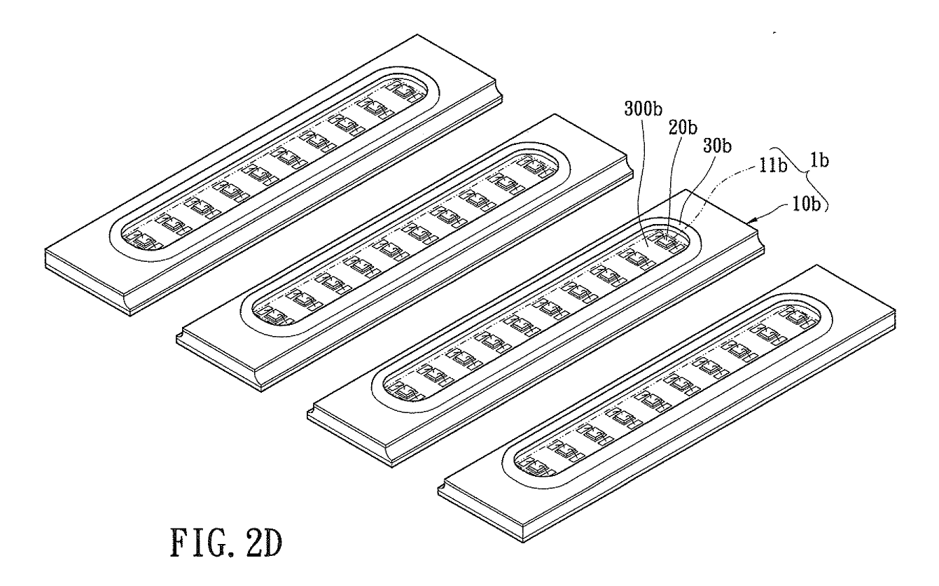

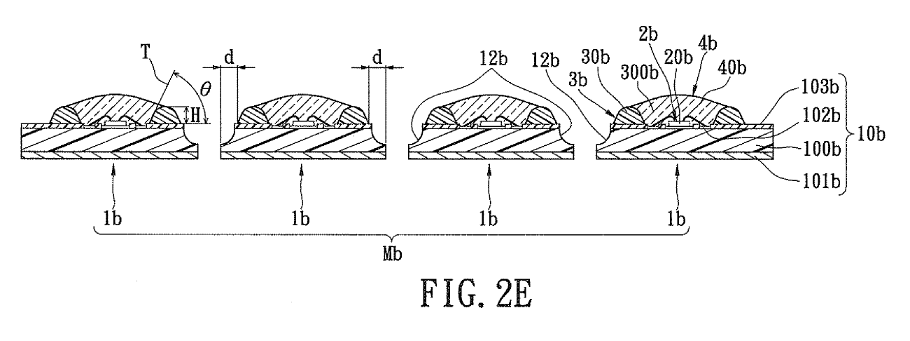

Referring to FIG. 2, the second embodiment of the present invention provides a method of manufacturing an LED package structure with external cutting chamfer. The method includes: providing a substrate module composed of a plurality of substrate units (the substrate module has a plurality of concave grooves and pressing areas formed on a top surface thereof, each concave groove is formed between every two substrate units, and each substrate unit has a substrate body and a chip-placing area disposed on a top surface of the substrate body); pressing every two pressing areas beside two opposite sides of each substrate unit in order to electrically arrange a plurality of LED chips on the chip-placing area of each substrate unit; cutting the substrate module along the concave grooves into the substrate units; surroundingly forming an annular reflecting resin body on the top surfaces of the substrate body of each substrate unit by coating (each annular reflecting resin body surrounds the LED chips that are disposed on each chip-placing area to form a resin position limiting space above each chip-placing area); and then forming a translucent package resin body on the top surface of the substrate body of each substrate unit in order to cover the LED chips (the position of each translucent package resin body is limited in each resin position limiting space).

Referring to FIGS. 2 and 2A-2E, the detail descriptions of the second embodiment of the present invention are shown as follows:

Referring to FIGS. 2 and 2A, the method includes providing a substrate module Mb composed of a plurality of substrate units 1b; wherein the substrate module Mb has a plurality of concave grooves Gb and pressing areas Pb formed on a top surface thereof (two of the pressing areas Pb are respectively formed on two opposite outermost sides of the substrate module Mb and the other pressing areas Pb are respectively formed over the concave grooves Gb), each concave groove Gb is formed between every two substrate units 1b, and each substrate unit 1b has a substrate body 10b and a chip-placing area 11b disposed on a top surface of the substrate body 10b (step S200). In addition, each concave groove Gb can be a V-shaped groove or a U-shaped groove. In the second embodiment, each concave groove Gb is a U-shaped groove.

Moreover, each substrate body 10b has a circuit substrate 100b, a heat-dissipating layer 101b disposed on a bottom surface of the circuit substrate 100b, a plurality of conductive pads 102b disposed on a top surface of the circuit substrate 100b, and an insulative layer 103b disposed on the top surface of the circuit substrate 100b in order to expose the conductive pads 102b. Hence, the heat-dissipating efficiency of the circuit substrate 100b is increased by using the heat-dissipating layer 101b, and the insulative layer 103b is a solder mask for exposing the conductive pads 102b only in order to achieve local soldering. However, the above-mentioned definition of the substrate body 10b does not limit the present invention. Any types of substrate can be applied to the present invention. For example, the substrate body 10b can be a PCB (Printed Circuit Board), a flexible substrate, an aluminum substrate, a ceramic substrate, or a copper substrate.

Referring to FIGS. 2 and 2B, the method includes pressing every two pressing areas Pb beside two opposite sides of each substrate unit 1b in order to electrically arrange a plurality of LED chips 20b on the chip-placing area 11b of each substrate unit 1b (step S202). In other words, designer can plan a predetermined chip-placing area 11b on the substrate unit 1b in advance, so that the LED chips 20b can be placed on the chip-placing area 11b of the substrate unit 1b. In the second embodiment, the LED chips 20b are electrically disposed on the chip-placing area 11b of the substrate unit 1b by wire bonding. In addition, when every two pressing areas Pb beside two opposite sides of each LED chip 20b are respectively pressed by two pressing elements B, the LED chips 20b can be electrically connected with the substrate bodies 10b by wire bonding in sequence.

Referring to FIGS. 2, 2B and 2C, the method includes cutting the substrate module Mb along the concave grooves Gb into the substrate units 1b (S204). In addition, two of the substrate units 1b are two outermost substrate units, and the other substrate units 1b are disposed between the two outermost substrate units.

Referring to FIGS. 2 and 2D, the method includes surroundingly forming an annular reflecting resin body 30b on the top surfaces of the substrate body 10b of each substrate unit 1b by coating; wherein each annular reflecting resin body 30b surrounds the LED chips 20b that are disposed on each chip-placing area 11b to form a resin position limiting space 300b above each chip-placing area 11b (step S206). In addition, the step of surroundingly forming each annular reflecting resin body 30b further includes: surroundingly coating liquid resin (not shown) on the top surface of the substrate body 10b of each substrate unit 1b, and then hardening the liquid resin to form the annular reflecting resin bodies 30b. Furthermore, the liquid resin can be coated on the substrate body 10b by any shapes according to different requirements (such as a circular shape, a square or a rectangular shape etc.). In addition, the annular reflecting resin body 30b can be a white thermohardening reflecting body (opaque resin) mixed with inorganic additive, and the cross section of the resin position limiting space 300b has a rectangular shape.

The thixotropic index of the liquid resin is between 4 and 6, the pressure of coating the liquid resin on the top surface of the substrate body 10b is between 350 kpa and 450 kpa, and the velocity of coating the liquid resin on the top surface of the substrate body 10b is between 5 mm/s and 15 mm/s. The liquid resin is surroundingly coated on the top surface of the substrate body 10b from a start point to a termination point, and the position of the start point and the position of the termination point are the same. In addition, the liquid resin is hardened by baking, the baking temperature is between 120° C. and 140° C., and the baking time is between 20 minute and 40 minute.

Referring to FIGS. 2 and 2E, the method includes forming a translucent package resin body 40b on the top surface of the substrate body 10b of each substrate unit 1b in order to cover the LED chips 20b; wherein the position of each translucent package resin body 40b is limited in each resin position limiting space 300b (step S208) in order to finish the manufacture of each LED package structure with external cutting chamfer. In addition, the top surface of each translucent package resin body 40b can be convex, concave or plane. In the second embodiment, the top surface of each translucent package resin body 40b is convex.

Furthermore, referring to FIG. 1E, each annular reflecting resin body 30b has an arc shape formed on a top surface thereof. Each annular reflecting resin body 30b has a radius tangent T, and the angle θ of the radius tangent T relative to the top surface of the substrate body 10b of each substrate unit 1b is between 40° C. and 50° C. The maximum height H of each annular reflecting resin body 30b relative to the top surface of the substrate body 10b of each substrate unit 1b is between 0.3 mm and 0.7 mm, and the width of a bottom side of each annular reflecting resin body 30b is between 1.5 mm and 3 mm. The thixotropic index of each annular reflecting resin body 30b is between 4 and 6.

In the second embodiment, each LED chip 20b can be a blue LED chip, and each translucent package resin body 40b can be a phosphor body. Hence, blue light beams (not shown) generated by the LED chips 20b (the blue LED chips) can pass through the translucent package resin body 40b (the phosphor body) to generate white light beams (not shown) that are similar to the light source generate by sun lamp.

Furthermore, two of the substrate units 1b are two outermost substrate units, and the other substrate units 1b are disposed between the two outermost substrate units, so that the substrate body 10b of each outermost substrate unit 1b has a cutting chamfer 12b formed on one side thereof and the substrate body 10b of each of the other substrate units 1b has two cutting chamfers 12b respectively formed on two opposite sides thereof. Moreover, a distance d between an outermost side of each annular reflecting resin body 30b and an outermost side of each substrate body 10b is between 0 and 1.5 mm. If the distance d between the outermost side of each annular reflecting resin body 30b and the outermost side of each substrate body 10b is 0 mm, the surface of the outermost side of each annular reflecting resin body 30b and the surface of the outermost side of each substrate body 10b are on the same plane.

Hence, when every two pressing areas Pb (as shown in FIG. 2B) beside two opposite sides of each LED chip 20b are respectively pressed by two pressing elements B, each LED chip 20b can be electrically disposed on the substrate body 10b by a wire bonding process without increasing the width of the substrate body 10b. In other words, the width of the empty area of the top surface of each substrate body 10b of each LED package structure is very narrow. That is the same as the above-mentioned definition of the distance d between 0 and 1.5 mm. Therefore, the width of the empty area is between 0 and 1.5 mm.

Hence, referring to FIGS. 1 and 2, the present invention provides a method of manufacturing an LED package structure with external cutting chamfer, including: providing a substrate module composed of a plurality of substrate units; wherein the substrate module has a plurality of concave grooves and pressing areas formed on a top surface thereof, each concave groove is formed between every two substrate units, and each substrate unit has a substrate body and a chip-placing area disposed on a top surface of the substrate body; pressing every two pressing areas beside each substrate unit in order to electrically disposed a plurality of LED chips on the chip-placing area of each substrate unit; and then selectively executing step (a) or (b).

Moreover, the step (a) is: surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; forming a translucent package resin body on the top surface of the substrate body of each substrate unit in order to cover the LED chips, wherein the position of each translucent package resin body is limited in each resin position limiting space; and cutting the substrate module along the concave grooves into the substrate units.

Furthermore, the step (b) is: cutting the substrate module along the concave grooves into the substrate units; surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; and forming a translucent package resin body on the top surface of the substrate body of each substrate unit in order to cover the LED chips, wherein the position of each translucent package resin body is limited in each resin position limiting space.

Referring to FIGS. 1E and 2E, the present invention provides an LED package structure with external cutting chamfer according to the above-mentioned manufacturing method. The LED package structure includes a substrate unit (1a, 1b), a light-emitting unit (2a, 2b), a light-reflecting unit (3a, 3b) and a package unit (4a, 4b). The substrate unit (1a, 1b) has a substrate body (10a, 10b) and a chip-placing area (11a, 11b) disposed on a top surface of the substrate body (10a, 10b). The light-emitting unit (2a, 2b) has a plurality of LED chips (20a, 20b) electrically disposed on the chip-placing area (11a, 11b).

Moreover, two of the substrate units (1a, 1b) are two outermost substrate units, and the other substrate units (1a, 1b) are disposed between the two outermost substrate units, so that the substrate body (10a, 10b) of each outermost substrate unit (1a, 1b) has a cutting chamfer (12a, 12b) formed on one side thereof and the substrate body (10a, 10b) of each of the other substrate units (1a, 1b) has two cutting chamfers (12a, 12b) respectively formed on two opposite sides thereof.

The light-reflecting unit (3a, 3b) has an annular reflecting resin body (30a, 30b) surroundingly formed on the top surface of the substrate body (10a, 10b) by coating. A distance d between a outermost side of the annular reflecting resin body (30a, 30b) and a outermost side of the substrate body (10a, 10b) is between 0 and 1.5 mm, and the annular reflecting resin body (30a, 30b) surrounds the LED chips (20a, 20b) that are disposed on the chip-placing area (11a, 11b) to form a resin position limiting space (300a, 300b) above the chip-placing area (11a, 11b).

In addition, the package unit (4a, 4b) has a translucent package resin body (40a, 40b) disposed on the top surface of the substrate body (10a, 10b) in order to cover the LED chips (20a, 20b), and the position of the translucent package resin body (40a, 40b) is limited in the resin position limiting space (300a, 300b).

In conclusion, when every two pressing areas beside two opposite sides of each LED chip are respectively pressed by two pressing elements, each LED chip can be electrically disposed on the substrate body by a wire bonding process without increasing the width of the substrate body. In other words, the width of the empty area of the top surface of each substrate body of each LED package structure is very narrow. That is the same as the above-mentioned definition of the distance between 0 and 1.5 mm. Therefore, the width of the empty area is between 0 and 1.5 mm.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. An LED package structure with external cutting chamfer, comprising:
a substrate unit having a substrate body and a chip-placing area disposed on a top surface of the substrate body, wherein the substrate body has a cutting chamfer formed on one side thereof;
a light-emitting unit having a plurality of LED chips electrically disposed on the chip-placing area;
a light-reflecting unit having an annular reflecting resin body surroundingly formed on the top surface of the substrate body by coating, wherein a distance between an outermost side of the annular reflecting resin body and an outermost side of the substrate body is between 0 and 1.5 mm, and the annular reflecting resin body surrounds the LED chips that are disposed on the chip-placing area to form a resin position limiting space above the chip-placing area; and
a package unit having a translucent package resin body disposed on the top surface of the substrate body in order to cover the LED chips, wherein the position of the translucent package resin body is limited in the resin position limiting space.

2. The LED package structure according to claim 1, wherein the substrate body has a circuit substrate, a heat-dissipating layer disposed on a bottom surface of the circuit substrate, a plurality of conductive pads disposed on a top surface of the circuit substrate, and an insulative layer disposed on the top surface of the circuit substrate in order to expose the conductive pads.

3. The LED package structure according to claim 1, wherein each LED chip is a blue LED chip, and the translucent package resin body is a phosphor body.

4. The LED package structure according to claim 1, wherein the resin position limiting space has a cross section as a rectangular shape.

5. The LED package structure according to claim 1, wherein the annular reflecting resin body has an arc shape formed on a top surface thereof.

6. The LED package structure according to claim 1, wherein the annular reflecting resin body has a radius tangent and the angle of the radius tangent relative to the top surface of the substrate body is between 40° C. and 50° C., the maximum height of the annular reflecting resin body relative to the top surface of the substrate body is between 0.3 mm and 0.7 mm, the width of a bottom side of the annular reflecting resin body is between 1.5 mm and 3 mm, and the thixotropic index of the annular reflecting resin body is between 4 and 6.

7. The LED package structure according to claim 1, wherein the annular reflecting resin body is a white thermohardening reflecting body mixed with inorganic additive.

8. An LED package structure with external cutting chamfer, comprising:
a substrate unit having a substrate body and a chip-placing area disposed on a top surface of the substrate body, wherein the substrate body has two cutting chamfers respectively formed on two opposite sides thereof;
a light-emitting unit having a plurality of LED chips electrically disposed on the chip-placing area;
a light-reflecting unit having an annular reflecting resin body surroundingly formed on the top surface of the substrate body by coating, wherein a distance between an outermost side of the annular reflecting resin body and an outermost side of the substrate body is between 0 and 1.5 mm, and the annular reflecting resin body surrounds the LED chips that are disposed on the chip-placing area to form a resin position limiting space above the chip-placing area; and
a package unit having a translucent package resin body disposed on the top surface of the substrate body in order to cover the LED chips, wherein the position of the translucent package resin body is limited in the resin position limiting space.

9. The LED package structure according to claim 8, wherein the resin position limiting space has a cross section as a rectangular shape, the annular reflecting resin body has an arc shape formed on a top surface thereof, the annular reflecting resin body has a radius tangent and the angle of the radius tangent relative to the top surface of the substrate body is between 40° C. and 50° C., the maximum height of the annular reflecting resin body relative to the top surface of the substrate body is between 0.3 mm and 0.7 mm, the width of a bottom side of the annular reflecting resin body is between 1.5 mm and 3 mm, the thixotropic index of the annular reflecting resin body is between 4 and 6, and the annular reflecting resin body is a white thermohardening reflecting body mixed with inorganic additive.

10. A method of manufacturing an LED package structure with external cutting chamfer, comprising:
providing a substrate module composed of a plurality of substrate units, wherein the substrate module has a plurality of concave grooves and pressing areas formed on a top surface thereof, each concave groove is formed between every two substrate units, and each substrate unit has a substrate body and a chip-placing area disposed on a top surface of the substrate body;
pressing every two pressing areas beside two opposite sides of each substrate unit in order to electrically arrange a plurality of LED chips on the chip-placing area of each substrate unit; and
selectively executing step (a) or (b), wherein the step (a) is: surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; forming a translucent package resin body on the top surface of the substrate body of each substrate unit in order to cover the LED chips, wherein the position of each translucent package resin body is limited in each resin position limiting space; and cutting the substrate module along the concave grooves into the substrate units; the step (b) is: cutting the substrate module along the concave grooves into the substrate units; surroundingly forming an annular reflecting resin body on the top surfaces of the substrate body of each substrate unit by coating, wherein each annular reflecting resin body surrounds the LED chips that are disposed on each chip-placing area to form a resin position limiting space above each chip-placing area; and forming a translucent package resin body on the top surface of the substrate body of each substrate unit in order to cover the LED chips, wherein the position of each translucent package resin body is limited in each resin position limiting space.

11. The method according to claim 10, wherein the step of surroundingly forming each annular reflecting resin body further comprises: surroundingly coating liquid resin on the top surface of the substrate body of each substrate unit, and then hardening the liquid resin to form the annular reflecting resin bodies.

12. The method according to claim 11, wherein the liquid resin is hardened by baking, the baking temperature is between 120° C. and 140° C., the baking time is between 20 minute and 40 minute, the pressure of coating the liquid resin on the top surface of the substrate body is between 350 kpa and 450 kpa, the velocity of coating the liquid resin on the top surface of the substrate body is between 5 mm/s and 15 mm/s.

13. The method according to claim 11, wherein the liquid resin is surroundingly coated on the top surface of the substrate body of each substrate unit from a start point to a termination point, and the position of the start point and the position of the termination point are the same.

14. The method according to claim 10, wherein the substrate body has a circuit substrate, a heat-dissipating layer disposed on a bottom surface of the circuit substrate, a plurality of conductive pads disposed on a top surface of the circuit substrate, and an insulative layer disposed on the top surface of the circuit substrate in order to expose the conductive pads.

15. The method according to claim 10, wherein each LED chip is a blue LED chip, each translucent package resin body is a phosphor body, and the top surface of each translucent package resin body is convex, concave or plane.

16. The method according to claim 10, wherein the resin position limiting space has a cross section as a rectangular shape, the annular reflecting resin body has an arc shape formed on a top surface thereof, and the annular reflecting resin body is a white thermohardening reflecting body mixed with inorganic additive.

17. The method according to claim 10, wherein each annular reflecting resin body has a radius tangent, and the angle of the radius tangent relative to the top surface of the substrate body of each substrate unit is between 40° C. and 50° C., the maximum height of each annular reflecting resin body relative to the top surface of the substrate body of each substrate unit is between 0.3 mm and 0.7 mm, the width of a bottom side of each annular reflecting resin body is between 1.5 mm and 3 mm, and the thixotropic index of each annular reflecting resin body is between 4 and 6.

18. The method according to claim 10, wherein each concave groove is a V-shaped groove or a U-shaped groove, and two of the pressing areas are respectively formed on two opposite outermost sides of the substrate module and the other pressing areas are respectively formed over the concave grooves.

19. The method according to claim 10, wherein two of the substrate units are two outermost substrate units, the other substrate units are disposed between the two outermost substrate units, the substrate body of each outermost substrate unit has a cutting chamfer formed on one side thereof, and the substrate body of each of the other substrate units has two cutting chamfers respectively formed on two opposite sides thereof.

20. The method according to claim 10, wherein a distance between an outermost side of each annular reflecting resin body and an outermost side of each substrate body is between 0 and 1.5 mm.
